(19) United States
(12) Patent Application Publication
(10) Pub. No.: US 2004/0108578 A1
(43) Pub. Date: Jun. 10, 2004

(54) Leadframe and method for manufacturing the same

(76) Inventors: Jae-Hong Kim, Cheonan-city (KR); Heui-Seog Kim, Cheonan-city (KR)

Correspondence Address: HARNESS, DICKEY & PIERCE, P.L.C., P.O. BOX 8910, RESTON, VA, 20195, US

(21) Appl. No.: 10/702,549

(22) Filed: Nov. 7, 2003

(30) Foreign Application Priority Data
Dec. 4, 2002 (KR) 2002-76701

(51) Int. Cl. H01L 21/44

(52) U.S. Cl. 257/666

(57) ABSTRACT

Locking tape is adhered to lower surfaces of the inner leads before cutting the inner lead tips, and the inner lead tips and the locking tape are then cut simultaneously.

### BACKGROUND OF THE INVENTION

This application claims the priority of Korean Patent Application No. 2002-76701, filed on Dec. 4, 2002, in the Korean Intellectual Property Office, the disclosure of which is incorporated herein in its entirety by reference.

1. Field of the Invention

The present invention generally relates to a semiconductor package, and more particularly, to a leadframe used as a raw material for manufacturing a semiconductor package.

2. Description of the Related Art

Together with gold wires and an epoxy mold compound (EMC), a leadframe may be an indispensable material for manufacturing a semiconductor package. Generally, leadframes may function to transfer heat generated by semiconductor packages, and may function as a carrier for transferring the chips from one step to another step during a manufacture of the semiconductor package. Further, the leadframes may function as a wire for connecting semiconductor packages, where the semiconductor packages may include chips mounted to a printed circuit board (PCB), and a frame for supporting the chips.

Generally, leadframes may be classified as either a stamped leadframe or an etched leadframe. The leadframes are normally classified depending on a manufacturing method used. In particular, the stamped leadframe may be manufactured by employing a mechanical process, such as a stamping process using a press. The etched leadframe may be manufactured by employing a chemical process, such as the use of photography in conjunction with chemicals to thereby carry out the etching.

FIG. 1 illustrates a flowchart of a method for manufacturing a lead-on-chip (LOC) type stamped leadframe, according to the conventional art. FIGS. 2 through 4 illustrate an LOC type stamped leadframe according to the conventional art.

Referring to FIGS. 1 through 4, a stamping process (refer to FIGS. 11 through 14) may be performed on a leadframe body 10 using a press finishing process (A1). Using such a process, a portion 12 of the leadframe body 10 may be removed. The removal of the portion 12 leaves an inner lead portion 14 intact. Sequentially, the leadframe body 10 may be cut along a line A-A′, by way of another punch, to obtain inner leads 14′ (A2). A piece of tape may then be adhered to lower surfaces of the inner leads 14′ (A3). If an LOC type stamped leadframe is used, a double-sided tape 16 may be used. The double-sided tape 16 may have adhesives on both sides of a base film that includes a polyimide material.

FIG. 5 illustrates an LOC type stamped leadframe manufactured according to the conventional art. Referring to FIG. 5, the LOC type stamped leadframe may have inner leads 7 formed inside of a damber line 5 and outer leads 9 formed outside of the damber line 5. The inner leads 7 may represent a portion encapsulated by EMC, when the semiconductor package is molded by EMC during a process for manufacturing a semiconductor package. The outer leads 9 may be exposed to the outside and may be used for connecting the semiconductor package to a PCB.

A piece of tape, for example, double-sided tape 8 having adhesive on both sides thereof, may be adhered on lower surfaces of tips 7a of the inner leads 7. Thus, a lower surface of the double-sided tape 8, on which the tips 7a are not adhered, is used for adhering a semiconductor chip to the lead frame, and an upper surface of the double-sided tape 8 is used for adhering the inner leads 7. Since the double-sided tape 8 is adhered to the inner lead tips 7a after the stamping process of the inner lead tips 7a is completed, the double-sided tape 8 has an area large enough to cover the inner lead tips 7a.

FIG. 6 illustrates a flowchart for explaining a method for manufacturing a general stamped leadframe according to the conventional art. FIGS. 7 through 9 illustrate a general stamped leadframe according to the conventional art.

Referring to FIGS. 6 through 9, a stamping process for a leadframe body 10 may be preformed (B1). In particular, a portion 12 may be removed by a press punch. Removing the portion 12 leaves inner leads 14 in the leadframe body 10. Sequentially, a piece of tape, for example, one-sided tape 18, which has an adhesive only on one side thereof may be adhered on upper surfaces of the inner leads 14 (B2). The one-sided tape 18 is not adhered to tips of the inner leads 14. Instead, the one-sided tape 18 is positioned a predetermined distance from the inner lead tips. The reason is that an Ag plating process is performed at the inner lead tips to facilitate a second stitch bonding during a wire-bonding process of the semiconductor packaging process. The leadframe body 10 may then be cut along a line A-A′ using the press punch. The cut is used to obtain inner leads 14′ (B3).

According the conventional art, the inner lead tips are cut and then the double-sided tape is adhered the LOC type stamped leadframe. However, the inner lead tips may shift right and left or up and down due to a potential stress that occurs during the stamping process and the stress of the inner lead tips generated during the process for cutting the inner lead tips. This may be considered a disadvantage of the conventional art.

Further, since one-sided tape is adhered separated from the inner lead tips by a predetermined distance and the inner lead tips are then cut according to the conventional method, the inner lead tips may shift or tilt due to the stress on the inner lead tips, which is generated during the stamping process and the cutting process. This may be considered a further disadvantage of the conventional art

As described above, methods for manufacturing the LOC type stamped leadframe and the general stamped leadframe according to the conventional art may have the following disadvantages.

First, the coplanarity of the inner leads may be reduced, or spaces between the inner leads may not be consistent due to the shifting of the inner lead tips. As a result, a fine-pitch leadframe in which spaces between inner leads are fine may be difficult to achieve.

Second, if the space between the inner leads is not consistent, a video lead location (VLL) function of a wire bonder should be be used to compensate for the irregular spaces between the inner leads. However, the throughput time of the wire bonding process may be prolonged because of the VLL function. Further, if the shifting of the inner lead tips is excessive, the wire bonder may not find the locations of the inner leads at all, thereby producing a defective semiconductor package.

### SUMMARY OF THE INVENTION

An exemplary embodiment of the present invention provides a device, including a leadframe body having leads; a plurality of inner leads formed in the leadframe body; and locking tape adhered to tips of the plurality of inner leads, the locking tape being cut together with the inner leads.

An exemplary embodiment of the present invention provides a method, including performing a stamping process for forming inner leads in a leadframe member; adhering locking tape to tips of the inner leads; and simultaneously cutting the inner lead tips and the locking tape.

An exemplary embodiment of the present invention provides a device, including a leadframe body including a plurality of leads; and tape adhered to the plurality of leads, the tape ending at an end of each of the plurality of leads.

An exemplary embodiment of the present invention provides a method, including adhering tape to leads of a leadframe; and cutting the tape and a portion of the leads simultaneously, the cutting of the tape resulting in an edge of the tape being defined along tips of the leads.

### BRIEF DESCRIPTION OF THE DRAWINGS

The above and other aspects and advantages of the present invention will become more apparent by describing in detail preferred embodiments thereof with reference to the attached drawings in which:

FIG. 1 illustrates a flowchart of a method for manufacturing a lead-on-chip (LOC) type stamped leadframe, according to the conventional art;

FIGS. 2 through 4 illustrate an LOC type stamped leadframe according to the conventional art;

FIG. 5 illustrates an LOC type stamped leadframe manufactured according to the conventional art;

FIG. 6 illustrates a flowchart for explaining a method for manufacturing a general stamped leadframe according to the conventional art;

FIGS. 7 through 9 illustrate a general stamped leadframe according to the conventional art;

FIG. 10 illustrates a flowchart summarizing a method for manufacturing a stamped leadframe according to an exemplary embodiment;

FIGS. 11 through 14 illustrate cross-sectional views for explaining a general stamping process according to an exemplary embodiment of the present invention;

FIGS. 15 through 17 are views for explaining a method for manufacturing a stamped leadframe according to an exemplary embodiment of the present invention;

FIG. 18 is an electron microscope photograph of inner lead tips of a stamped leadframe according to the conventional art; and

FIG. 19 is an electron microscope photograph of inner lead tips of a stamped leadframe according to an exemplary embodiment of the present invention.

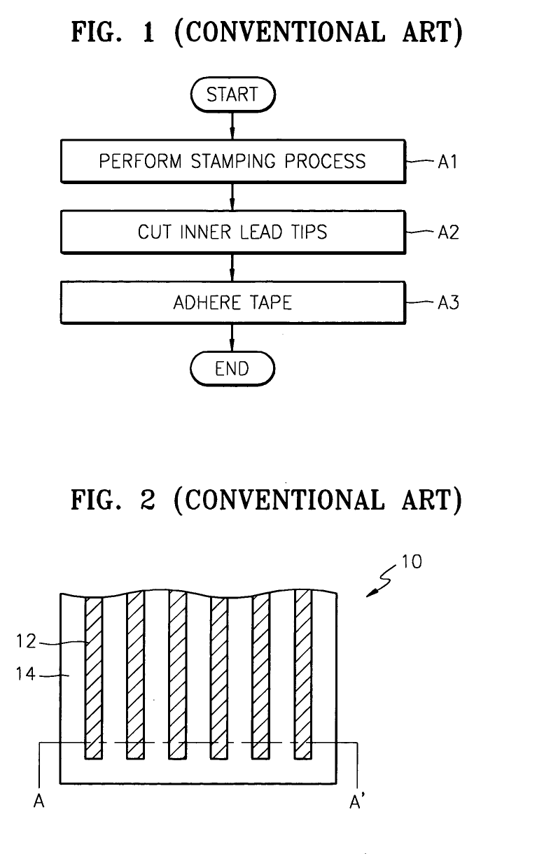

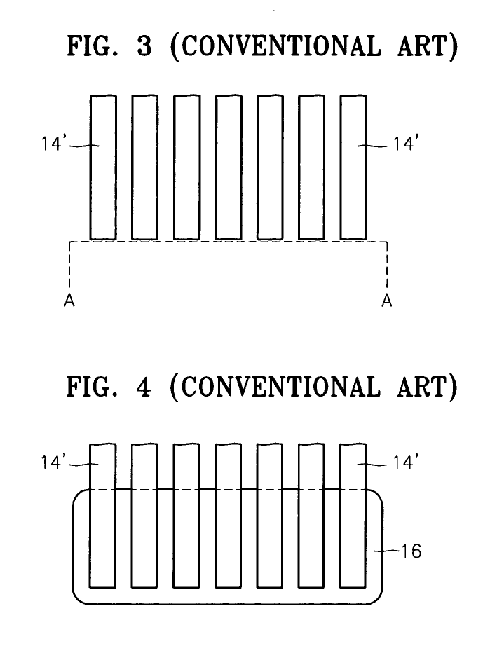

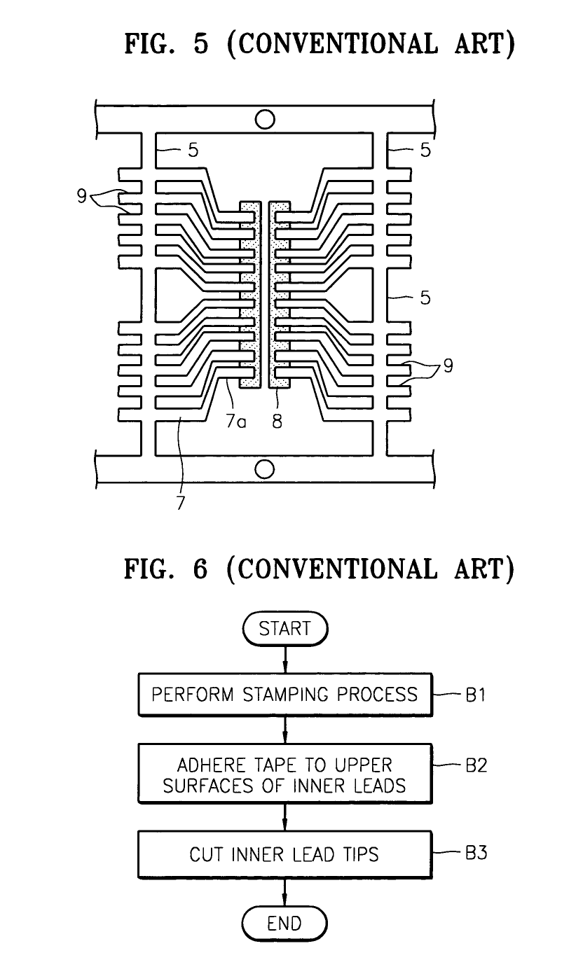

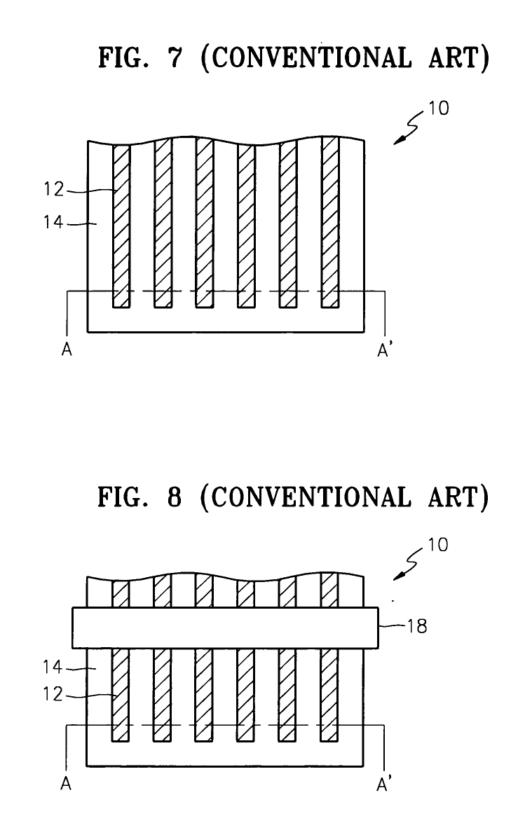

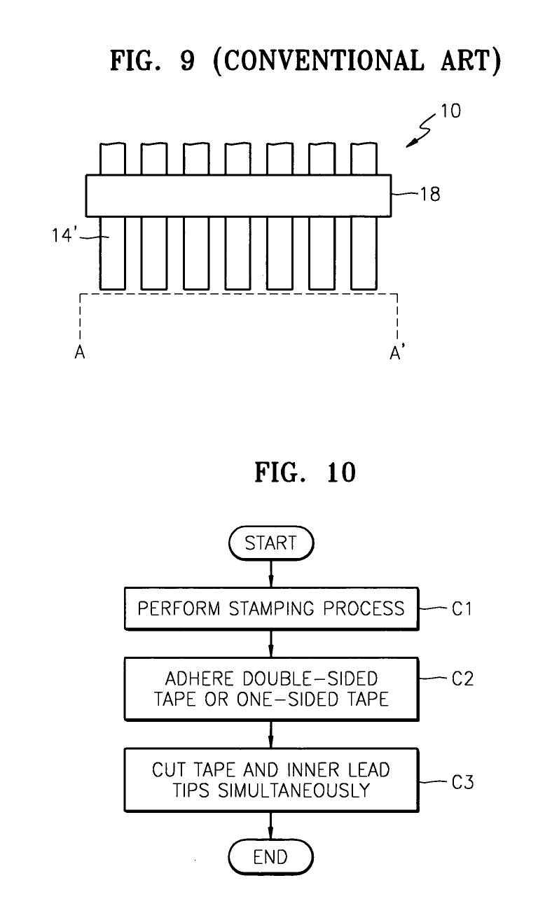

### DETAILED DESCRIPTION OF EXEMPLARY EMBODIMENTS OF THE PRESENT INVENTION

Exemplary embodiments of the present invention will now be described more fully with reference to the accompanying drawings. However, it will be understood by those of ordinary skill in the art that various changes in form and details may be made without departing from the spirit and scope of the present invention as defined by the claims.

The term stamped leadframe referred to the specification is broadly used and is not to be limited to a specific type of leadframe For example, a lead-on-chip (LOC) type leadframe described herein is used by way of example only. Various changes in form and details may be made without departing from the spirit and scope of the present invention. For example, although double-sided tape is adhered to lower surfaces of inner leads in a case of using a LOC type stamped leadframe in an exemplary embodiment, one-sided tape may be used in a case of using a general stamped leadframe. Further, the double-sided tape and the one-sided tape may be replaced with a similar material such as an adhesive. Thus, exemplary embodiments are shown by way of example only in the drawings. That is, the present invention is not limited to the exemplary embodiments set forth herein.

FIG. 10 illustrates a flowchart summarizing a method for manufacturing a stamped leadframe according to an exemplary embodiment.

According to a method for manufacturing inner leads tips of a stamped leadframe according to an exemplary embodiment of the present invention, a stamping process for forming inner leads may be performed (C1). Locking tape may adhered to lower surfaces of the inner leads (C2). Here, double-sided tape having an adhesive on both sides thereof may be used as the locking tape when using a LOC type stamped leadframe, and one-sided tape having an adhesive on only one side to which the inner leads are adhered may be used as the locking tape when using a general stamped leadframe. The purpose for adhering the locking tape is to suppress shifting of the inner lead tips by fixing the inner lead tips before cutting thereof.

Finally, the inner lead tips are cut in a state where the inner lead tips are fixed by the locking tape (C3). Because the locking tape is adhered to the lower surfaces of the inner lead tips and fixes the inner lead tips, the right-and-left or up-and-down shifting of the inner lead tips due to stress generated during the cutting process of the inner lead tips can be substantially suppressed.

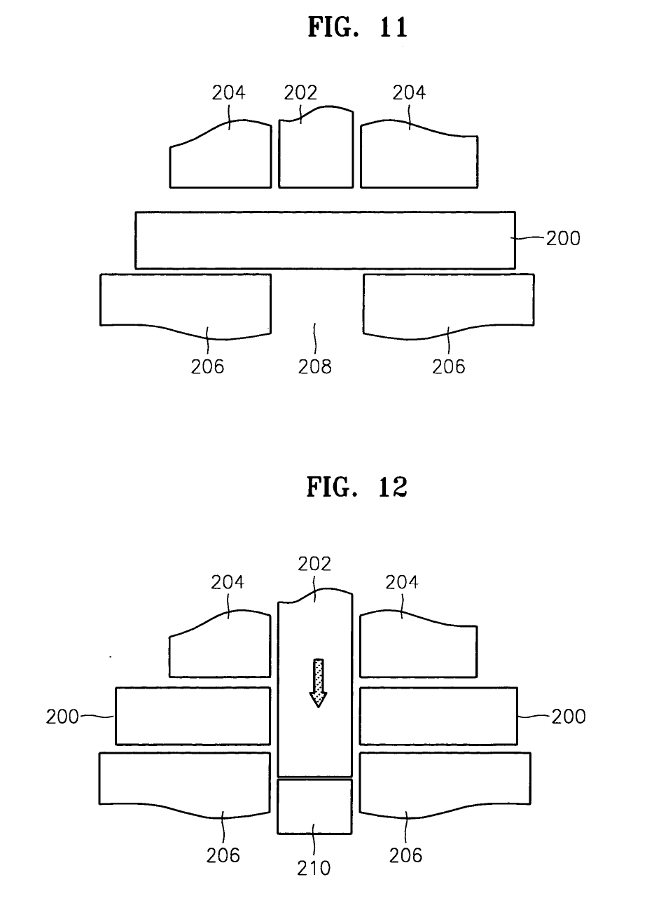

FIGS. 11 through 14 illustrate cross-sectional views for explaining a general stamping process according to an exemplary embodiment of the present invention.

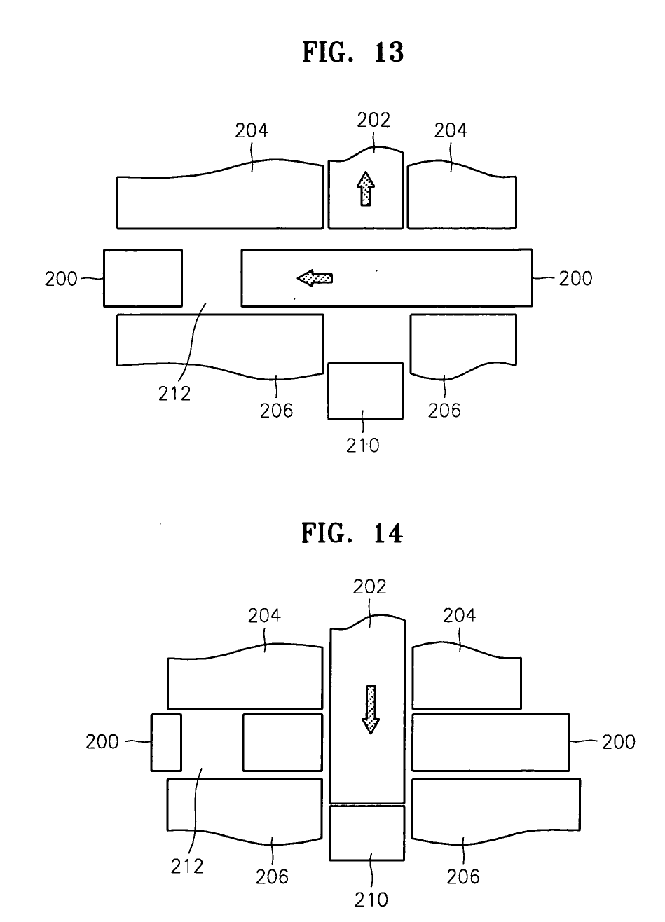

Referring to FIGS. 11 through 14, a main finishing unit of a press tool for performing a stamping process may include a stripper 204, a die 206, and a punch 202. A stamped leadframe having a desirable shape is completed by simultaneously striking the entire leadframe member 200, which is formed on the die 206 and is fixed by the stripper 204, using the punch 202 or sequentially striking a portion of the leadframe member 200. FIG. 11 shows a state before the stamping process of the leadframe member 200 fixed by the stripper 204 and the die 206 is performed using the punch 202. FIG. 12 shows a state of performing a first stamping process, FIG. 13 shows a state where the leadframe member 200 moves to the left after the first stamping process is completed, and FIG. 14 shows a state of performing a second stamping process.

In the above general stamping process, a mechanical force may be applied to the narrow space of the leadframe member 200 using the punch 202, the die 206, and the stripper 204 to make the leadframe member 200 into a desirable shape. However, since the mechanical force is applied to the leadframe member 200 during the stamping process, the leadframe member 200 may be deformed, thereby resulting in it being cut. At this time, much stress is accumulated on the leadframe member 200, and as a result, the leadframe member 200 may be shifted, tilted, or bent due to the stress.

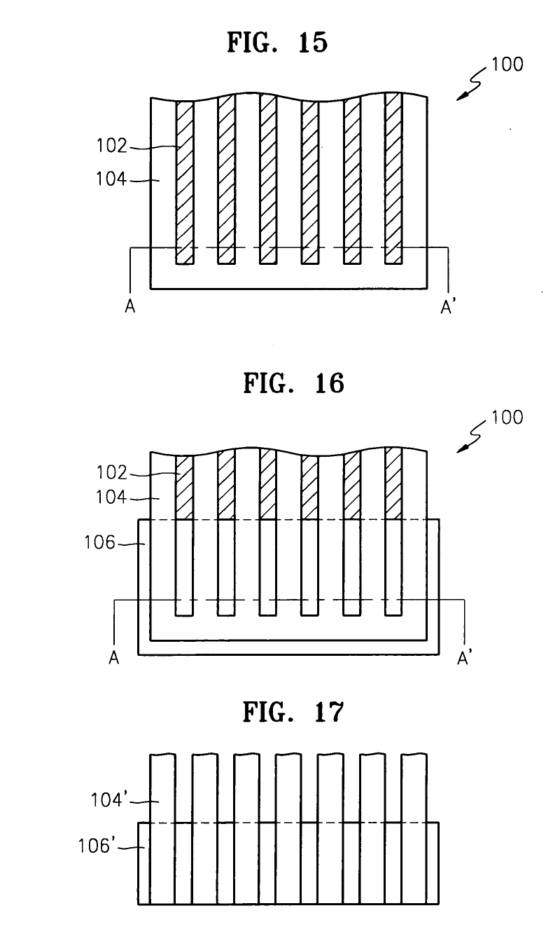

FIGS. 15 through 17 are views for explaining a method for manufacturing a stamped leadframe according to an exemplary embodiment of the present invention.

Referring to FIGS. 15 through 17, the stamping process described in FIGS. 11 through 14 may be performed on a leadframe body 100 so that portions 102 except inner leads 104 in the leadframe body 100 are removed using the punch. Sequentially, locking tape 106, for example, double-sided tape or one-sided tape having an area large enough to cover tips of the inner leads 104 may be adhered to lower surfaces of the inner leads 104. The locking tape 106 may be adhered to the inner leads 104 using the punch by generating adhesive strength on a surface thereof by way of heat.

Finally, inner leads 104′ as shown in FIG. 17 may be completed by simultaneously cutting the locking tape 106 and the tips of the inner leads 104 fixed by the locking tape 106.

Here, since the tips of the inner leads 104 are cut in a state where the tips are fixed by the locking tape 106, the locking tape 106 absorbs the stresses generated during the cutting process, thereby suppressing shifting of the tips.

Thus, shifting of the tips of the inner leads 104 may be reduced. In an exemplary embodiment of the present invention, manufacturing problems of a fine-pitch stamped leadframe caused by the shifting of the inner lead tips of the above-described leadframe according to the conventional are may be reduced. Further, since a wire-bonding process is smoothly performed without using a VLL function during the wire-bonding process of the semiconductor packaging process, the throughput time may be reduced so that the productivity of the leadframe increases.

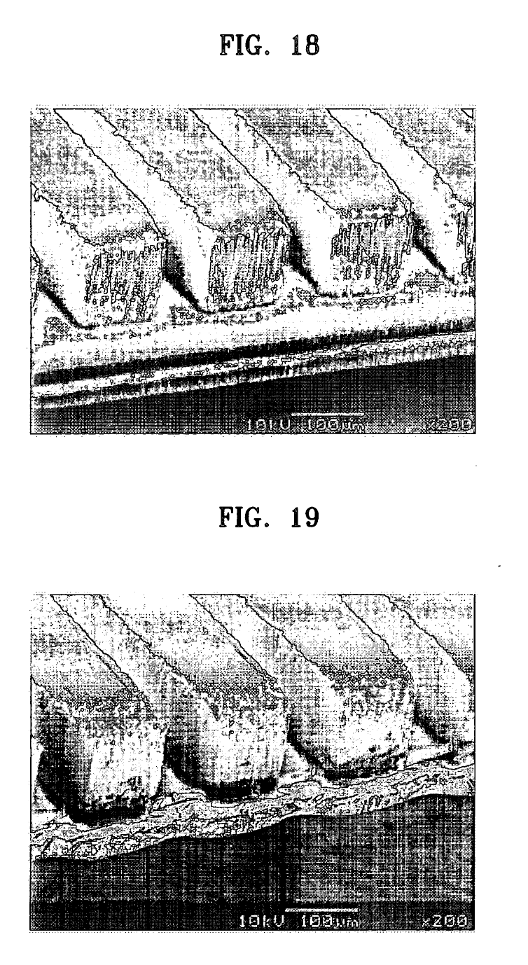

FIG. 18 is an electron microscope photograph of inner lead tips of a stamped leadframe according to the conventional art, and FIG. 19 is an electron microscope photograph of inner lead tips of a stamped leadframe according to an exemplary embodiment of the present invention.

As shown in FIG. 18, since the locking tape such as double-sided tape or one-sided tape is adhered to the inner leads after the inner lead tips are cut in the method for manufacturing the stamped leadframe according to the conventional art, the cut surfaces of the inner lead tips and an end portion of the locking tape are not aligned and perpendicular.

As shown in FIG. 19, since the inner lead tips and the locking tape are simultaneously cut using one punch, in the method for manufacturing the stamped leadframe according to an exemplary embodiment of the present invention, the cut surfaces of the inner lead tips and an end portion of the locking tape are aligned and perpendicular. Moreover, the end portion of the locking tape has the same cut shape as that of the cut surfaces of the inner lead tips.

As described above, exemplary embodiments of the present invention has the following advantages.

First, since shifting of inner lead tips, which is a significant problem in manufacturing a fine pitch type stamped leadframe, can be suppressed, the fine pitch type stamped leadframe may be easily manufactured using a general stamping process.

Second, since the right-and-left or up-and-down shifting of the inner lead tips, which is a main cause of a defective stamped leadframe, can be suppressed, the yield of the leadframe may increase.

Third, since a wire bonding process can be performed without using a VLL function during a wire bonding process of a semiconductor packaging process, the throughput time of the wire bonding process may be reduced, thereby increasing the productivity of the stamped leadframe.

It will be understood by those of ordinary skill in the art that various changes in form and details may be made without departing from the spirit and scope of exemplary embodiments of the present invention.

What is claimed is:

1. A device, comprising:
a leadframe body having leads;
a plurality of inner leads formed in the leadframe body; and
locking tape adhered to tips of the plurality of inner leads, the locking tape being cut together with the inner leads.

2. The device according to claim 1, wherein the inner leads are made using a stamping process.

3. The device according to claim 1, wherein the leadframe body is of a lead-on-chip (LOC) type.

4. The device according to claim 1, wherein the locking tape is double-sided tape which has an adhesive on both sides thereof.

5. The device according to claim 1, wherein the locking tape is one-sided tape having an adhesive on only one side thereof, the side having adhesive being adhered to the inner leads.

6. A method, comprising:
performing a stamping process for forming inner leads in a leadframe member;
adhering locking tape to tips of the inner leads; and
simultaneously cutting the inner lead tips and the locking tape.

7. The method of claim 6, wherein the leadframe is a LOC type.

8. The method of claim 6, wherein the locking tape is double-sided tape which has an adhesive on both sides thereof.

9. The method of claim 6, wherein the locking tape is one-sided tape having an adhesive on only one side thereof, the adhesive being adhered to the inner leads.

10. The method of claim 6, wherein the simultaneous cutting of the inner lead tips and the locking tape is performed using one punch.

11. A device, comprising:
a leadframe body including a plurality of leads; and
tape adhered to the plurality of leads, the tape ending at an end of each of the plurality of leads.

12. The device according to claim 11, wherein the tape is double sided tape having adhesive on both sides thereof.

13. The device according to claim 11, wherein the tape is single sided tape having adhesive on only one side thereof.

14. The device according to claim 12, wherein the leadframe body is a LOC type stamped leadframe.

15. The device according to claim 13, wherein the leadframe body is a general stamped leadframe.

16. A method, comprising:
adhering tape to leads of a leadframe; and
cutting the tape and a portion of the leads simultaneously, the cutting of the tape resulting in an edge of the tape being defined along tips of the leads.

17. The method according to claim 16, wherein the tape is double sided tape having adhesive on both sides thereof.

18. The method according to claim 16, wherein the tape is single sided tape having adhesive on both sides thereof.

19. The method according to claim 17, wherein the leadframe body is a LOC type stamped leadframe.

20. The method according to claim 18, wherein the leadframe body is a general stamped leadframe.
